(19) United States
(12) Patent Application Publication
(10) Pub. No.: US 2026/0110737 A1
(43) Pub. Date: Apr. 23, 2026

(54) Method And Apparatus For Detection Of Open Switch Faults In Power Converters

(71) Applicant: The Regents of The University of Michigan, Ann Arbor, MI (US)

(72) Inventor: Taehyung KIM, Ann Anbor, MI (US)

(73) Assignee: The Regents of The University of Michigan, Ann Arbor, MI (US)

(21) Appl. No.: 19/353,789

(22) Filed: Oct. 9, 2025

Related U.S. Application Data
(60) Provisional application No. 63/708,832, filed on Oct. 18, 2024.

(51) Int. Cl. G01R 31/327; H02M 1/00

(52) U.S. Cl. CPC G01R 31/3275; H02M 1/0009

(57) ABSTRACT

A switch fault detection method based on a virtual admittance is proposed for detecting a switch fault in a power converter. A virtual admittance metric is created based on the virtual admittance to minimize potential influence by highly dynamic load change while reducing computation complexity to implement the technique in applications with highly dynamic loads. This technique uses a measured inductor current, and a digitally constructed inductor voltage based on a duty ratio of a PWM control signal, and a measured input and output voltage.

### CROSS-REFERENCE TO RELATED APPLICATIONS

This application claims the benefit of U.S. Provisional Application No. 63/708,832, filed on Oct. 18, 2024. The entire disclosure of the above application is incorporated herein by reference.

### GOVERNMENT CLAUSE

This invention was made with government support under 2321681 awarded by the National Science Foundation. The government has certain rights in the invention.

### FIELD

The present disclosure relates to detecting a switch fault in a power converter.

### BACKGROUND

For the power MOSFETS used for dc-dc converters, switch faults occur mostly because of bond wire degradation, gate-oxide degradation, cracks and delamination in the die-attach solder, and connector failure. Among existing switch fault diagnosis for non-isolated dc-dc converters, an auxiliary winding and a Rogowski coil sensor are used to extract fault indicators through the inductor voltage. The auxiliary winging and coil sensor based approaches require extra effort to install them in the existing inductors. The inductor current derivative, DC-link current derivative, and capacitor current derivative are also used to diagnose converter switch failure. The current methods with the current derivatives are sensitive to signal noise due to the derivative procedure. Magnetic near-field waveforms along with a fast-Fourier transform are utilized to detect switch faults. However, the cost of the magnetic probes to capture the waveforms and the computational burden for Fourier transformation are obstacles to use the method.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

This section provides a general summary of the disclosure, and is not a comprehensive disclosure of its full scope or all of its features.

The present disclosure presents a method for detecting a fault of a switch in a power converter. In this method, switch faults are detected accurately under high dynamic loads with reasonable computational effort. The method does not use extra coils or probes to lower system costs and does not consider derivatives and fast Fourier transformation. Rather, the method focuses on a virtual admittance of the converter inductance at a switching frequency based on observations that open-circuit fault does not create high-frequency inductor current ripple due to no switching operation occurring after the faults.

In one aspect of the disclosure, a method includes detecting a fault of a switch in a power converter. The switch is controlled by a pulse width modulated (PWM) control signal and powered by a power source. The method incudes measuring an inductor current passing through an inductor of the power converter, determining an inductor voltage across the inductor, extracting a high-frequency component of the inductor current at a switching frequency, extracting a high-frequency component of the inductor voltage at a switching frequency, calculating a magnitude of the high-frequency component of the inductor current, calculating a magnitude of the high-frequency component of the inductor voltage, defining a ratio of the magnitude of the high-frequency component of the inductor current to the magnitude of the high-frequency component of the inductor voltage, comparing the ratio to a fault threshold, and signaling a fault in the switch in response to the ratio being less than the fault threshold.

In one aspect, a method for detecting a fault of a switch in a power converter is presented. The switch is controlled by a pulse width modulated (PWM) control signal and powered by a power source. The method comprising measuring an inductor current through an inductor and determining an inductor voltage across the inductor. The inductor is electrically coupled between the power source and the switch. The method further comprises determining an inductor voltage across the inductor, extracting high-frequency component of the inductor current at a switching frequency, thereby forming an α-axis component of the inductor current, and extracting high-frequency component of the inductor voltage at a switching frequency, thereby forming an α-axis component of the inductor voltage. The method further comprises generating a β-axis component of the inductor current from the extracted high-frequency component of the inductor current, wherein the β-axis component of the inductor current is a 90 degree shift from the α-axis component of the inductor current, and generating a β-axis component of the inductor voltage from the extracted high-frequency component of the inductor voltage, wherein the β-axis component of the inductor voltage is a 90 degree phase shift from the α-axis component of the inductor voltage.

The method further comprises transforming the α-axis component and the β-axis component of the inductor current to a direct component and a quadrature component of the inductor current in accordance with a direct-quadrature-zero transformation and transforming the α-axis component and the β-axis component of the inductor voltage to a direct component and a quadrature component of the inductor voltage in accordance with a direct-quadrature-zero transformation. The method further comprises calculating a magnitude of the high-frequency component of the inductor current from the direct component and the quadrature component of the inductor current and calculating a magnitude of the high-frequency component of the inductor voltage from the direct component and the quadrature component of the inductor voltage. The method further comprises defining a virtual admittance metric as a ratio of the magnitude of the high-frequency component of the inductor current to the magnitude of the high-frequency component of the inductor voltage, comparing the virtual admittance to a fault threshold, and signaling a fault in the switch in response to the virtual admittance being less than the fault threshold.

In another aspect, the inductor voltage is derived from duty ratio of the PWM control signal, an input voltage of the power source and an DC link voltage for the power converter.

In another aspect, the high-frequency components of the inductor current and the high-frequency components of the inductor voltage are extracted using a band-pass filter.

In another aspect, the β-axis component of the inductor current and the β-axis component of the inductor voltage are generated using an all-pass filter.

In another aspect, a system includes a pulse width modulator generating a pulse width modulated (PWM) control signal, a power converter having an inductor and a switch receiving the pulse width modulated control signal and powered by a power source, and a current sensor generating a current signal corresponding to an inductor current passing through the inductor. A controller is programmed to determine an inductor voltage across the inductor, extract a high-frequency component of the inductor current at a switching frequency, thereby forming an α-axis component of the inductor current, extract a high-frequency component of the inductor voltage at a switching frequency, thereby forming an α-axis component of the inductor voltage, generate a β-axis component of the inductor current from the extracted high-frequency component of the inductor current, wherein the β-axis component of the inductor current is at 90 degree phase shift from the α-axis component of the inductor current, generate a β-axis component of the inductor voltage from the extracted high-frequency component of the inductor voltage, wherein the β-axis component of the inductor voltage is at 90 degree phase shift from the α-axis component of the inductor voltage, transform the α-axis component and the β-axis component of the inductor current to a direct component and a quadrature component of the inductor current in accordance with a direct-quadrature-zero transformation, transform the α-axis component and the β-axis component of the inductor voltage to a direct component and a quadrature component of the inductor voltage in accordance with a direct-quadrature-zero transformation, calculate a magnitude of the high-frequency component of the inductor current from the direct component and the quadrature component of the inductor current, calculating a magnitude of the high-frequency component of the inductor voltage from the direct component and the quadrature component of the inductor voltage, define a virtual admittance metric as a ratio of the magnitude of the high-frequency component of the inductor current to the magnitude of the high-frequency component of the inductor voltage, compare the virtual admittance metric to a fault threshold/. An indicator indicates the fault of a switch in a power converter in response to the virtual admittance being less than the fault threshold.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a diagram of a non-isolated dc-dc converter with optional sources for a single motor propulsion system;

FIG. 1B is a schematic of optional power sources and corresponding non-isolated dc-dc converters;

FIG. 2 is a flowchart of a switch fault detection method;

FIG. 3 is a block diagram of the switch fault detection method;

FIG. 4A is a graph showing steady-state simulation waveforms of a high-frequency component and a β-axis component of the inductor current;

FIG. 4B is a graph showing steady-state simulation waveforms of a direct component and quadrature component of the inductor current;

FIG. 5A is a graph showing steady-state simulation waveforms of a high-frequency component and a β-axis component of the inductor voltage;

FIG. 5B is a graph showing steady-state simulation waveforms of a direct component and quadrature component of the inductor voltage;

FIG. 6A is an example of a virtual admittance under different load changes; and

FIG. 6B is an example of the virtual admittance and a fault detection signal.

Corresponding reference numerals indicate corresponding parts throughout the several views of the drawings.

### DETAILED DESCRIPTION

Example embodiments will now be described more fully with reference to the accompanying drawings.

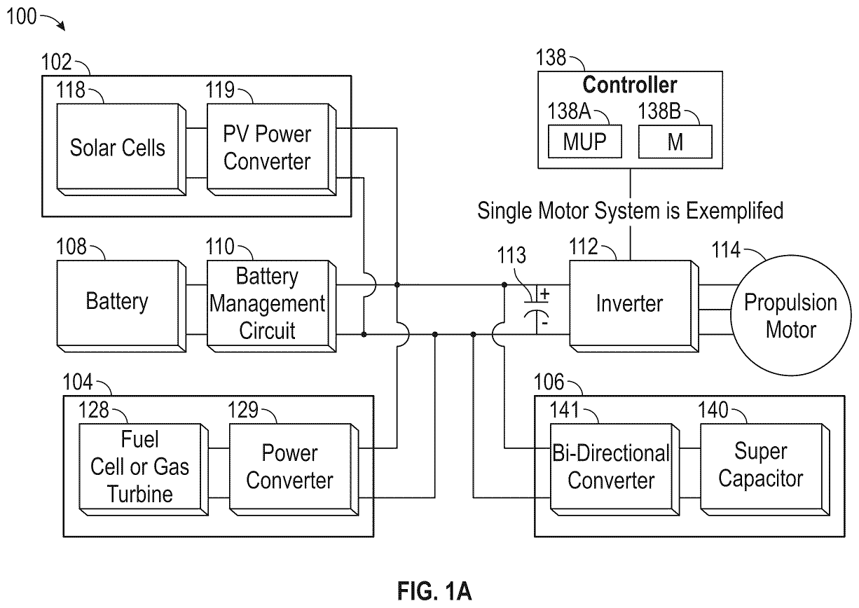

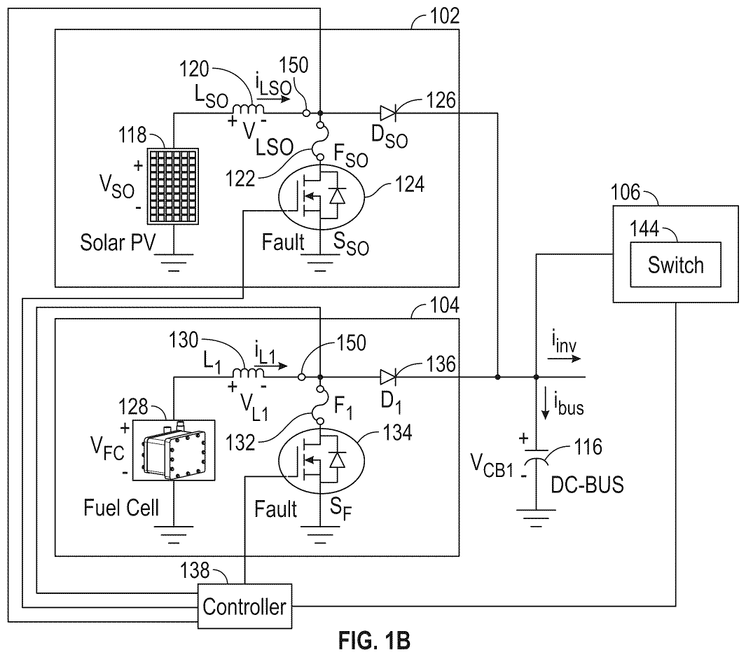

Referring now to FIG. 1A, an example block diagram of a hybrid configuration for a hybrid propulsion system 100 is set forth. The hybrid propulsion system 100 may include one or more solar cell circuits 102, a fuel cell circuit 104 and a supercapacitor circuit 106. The hybrid propulsion system 100 also includes a battery 108 and an associated battery management circuit 110, an inverter 112 associated with a DC link capacitor 113 across its inputs, a propulsion motor 114, and a controller 138 that includes a microprocessor 138A and a memory 138B. The microprocessor 138A may be referred to as a processor. Although one microprocessor 138A is illustrated, several may be used in the system. The memory 138B may be a non-transitory computer-readable medium that includes instructions that are executable by the processor. The instructions may include instructions for determining a switch fault.

One or more solar cells 118 of the solar cell circuit 102, a fuel cell 128 of the fuel cell circuit 104 and a supercapacitor 140 of the supercapacitor circuit 106 may serve as an optional power source for the propulsion system 100.

The solar cell circuit 102 may also include, in addition to the one or more solar cells 118, a power converter 119. The fuel cell circuit 104, in addition to the one or more fuel cells 128, a power converter 129. Similarly, the supercapacitor circuit 106 includes, in addition to the supercapacitor 140, a bi-directional converter 141. The battery management circuit 110 is interfaced between the battery 108 and the inverter 112 for the propulsion motor 114. The battery management circuit 110 controls the power output by or input to the battery 108.

During operation, the inverter 112 is configured to receive power from any one of the solar cells 118, the fuel cells 128 or the supercapacitor 140. The inverter 112 in turn converts the direct current (DC) input to an alternating current (AC) for driving the propulsion motor 114. The inverter 112 can also operate bi-directionally to convert an AC signal from the propulsion motor 114 to a DC input for the battery 108.

FIG. 1B further depicts an example of the solar panel circuit 102 and the fuel cell circuit 104. In an example embodiment, the solar panel circuit 102 is comprised of a solar panel 118, an inductor 120, a fuse 122, a switch 124, a diode 126 and a current sensor 150. In the example embodiment, the switch 124 is implemented by a metal-oxide-semiconductor field-effect transistor (MOSFET) although other implementations are contemplated by this disclosure.

Similarly, the fuel cell circuit 104 comprises a fuel cell 128, an inductor 130, a fuse 132, a switch 134 and a diode 136. In the example embodiment, the switch 134 is implemented by a metal-oxide-semiconductor field-effect transistor (MOSFET) although other implementations are contemplated by this disclosure. The solar panel circuit 102 and the fuel cell circuit 104 are electrically coupled via capacitor 116 to the inverter 112 as illustrated in FIG. 1A.

A switch 144 may also be incorporated into the bi-directional converter 141 of the supercapacitor circuit 106 in a similar way.

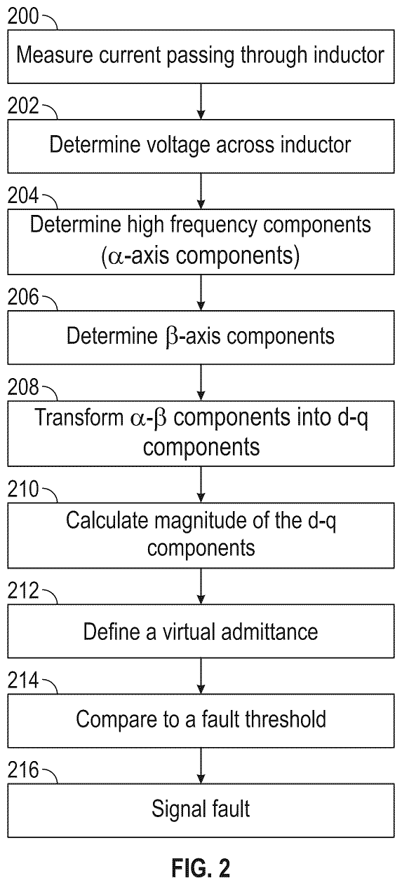

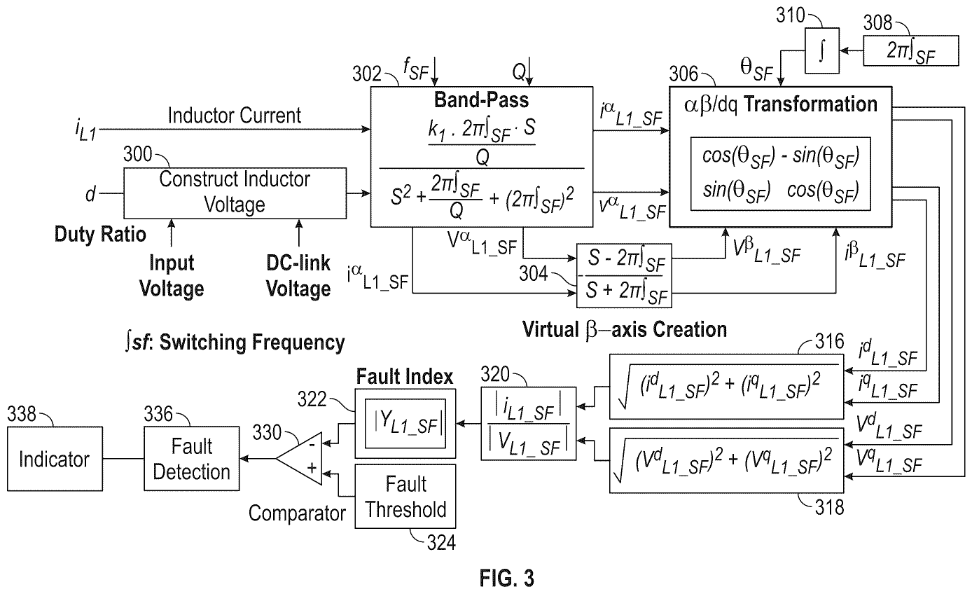

Referring now also to FIGS. 2 and 3, an example method for detecting a fault of a switch 124, 134, 144 in the power converter is set forth. The switch is controlled by a pulse width modulated (PWM) control signal received from the controller 138 and powered by a power source. In the example embodiment, a fault is detected in the switch 124 of the solar panel circuit 102 and/or the switch 134 of the fuel cell circuit 104. For explanation purposes, the description below will make reference to the fuel cell circuit 104.

As a starting point, the current passing through an inductor 130 is measured at 200, where the inductor is electrically coupled between the fuel cell 128 and the switch 134. This may be performed with the current sensor 150.

The voltage across the inductor 130 is also digitally constructed at 202 in the inductor voltage constructor 300 from the duty ratio d of the PWM control signal, an input voltage of the power source and a DC link voltage of the power converter (i.e., voltage across DC bus capacitor 116). More specifically, the inductor voltage is based on the state of the switch 124, 134, 144. When the switch is in an “on” state, the inductor voltage is equal to the input voltage of the power source minus the DC link voltage. When the switch is in an “off” state, the inductor voltage is equal to negative magnitude of the DC link voltage.

Next, high-frequency components of the inductor current and the inductor voltage are extracted at 204. In the example embodiment, the inductor voltage and the inductor current are extracted using a band-pass filter 302 as seen in FIG. 3. Specifically, the high-frequency components are extracted as follows:

$$\frac{{k}_{1} 2 π {f}_{s f} S}{{S}^{2} + \frac{2 π {f}_{s f}}{Q} + {( 2 π {f}_{s f} )}^{2}}$$

where f_{sf} is the switching frequency, k is a constant coefficient, S is a complex frequency variable, and Q is a Q-factor which is a reciprocal of the fractional bandwidth. The center frequency of the bandpass filter 302 should be the same as the switch frequency of the switch. The band-pass filter 302 outputs a α-axis inductor current (i_(L1_sf)\hat{ }α) and a α-axis inductor voltage (V_(L1_sf)\hat{ }α) which are the high-frequency components of the inductor current and the inductor voltage.

β-axis components of the inductor current and inductor voltage are also generated at 206, where the β-axis component of the inductor current is at 90 degree phase shift from the α-axis component of the inductor current and the β-axis component of the inductor voltage is at 90 degree phase shift from the α-axis component of the inductor voltage. In one example, β-axis components of the inductor current and inductor voltage are generated using an all-pass filter 302. In the all pass-filter 304, the β-axis components are generated according to:

$$- \frac{S - 2 π {f}_{sf}}{S + 2 π {f}_{sf}}$$

The all-pass filter 304 outputs the β-axis component of the inductor current (i_(L1_sf)\hat{ }β) and the β-axis component of the inductor voltage (V_(L1_sf)\hat{ }β). Because the α-axis components and the β-axis components (α-β components) of the inductor current and inductor voltage include only high-frequency components, they decrease to zero once a switch fault occurs.

At 208, the α-β components of the inductor current and the inductor voltage are transformed into direct components and quadrature components (d-q components) in accordance with a direct-quadrature-zero transformation. To do so, the α-β components are input into an α-β/d-q transformer 306 and the α-β/d-q transformer 306 performs a direct-quadrature-zero transformation. In the α-β/d-q transformer 306, the d-q components are determined based on a position of the switching frequency (OSF) input to the transformer 306 at block 308 and integral block 310 according to:

$${θ}_{S F} = \int 2 π {f}_{s f} d t$$

The α-β/d-q transformer 306 outputs the direct component of the inductor current (i_(L1_sf)\hat{ }d), the quadrature of the inductor current (i_(L1_sf)\hat{ }q), the direct component of the inductor voltage (V_(L1_sf)\hat{ }d), and the quadrature of the inductor voltage (V_(L1_sf)\hat{ }q).

At 210, a magnitude of the high-frequency components of the inductor current is calculated from the d-q components of the inductor current and a magnitude of the high-frequency components of the inductor voltage is calculated from the d-q components of the inductor voltage. For example, the d-q components of the inductor current are inputted into a current magnitude calculator 316. In the current magnitude calculator 316, the magnitude of the high-frequency components of the inductor current is calculated with the following equation:

$$\vert {i}_{L {1}_{S F}} \vert = \sqrt{{( {i}_{L {1}_{s f}}^{d} )}^{2} + {( {i}_{L {1}_{s f}}^{q} )}^{2}}$$

The current magnitude calculator 316 outputs the magnitude of the high-frequency components of the inductor current (|i_{L1}_{_{SF}}|). Similarly, the d-q components of the voltage are inputted into a voltage magnitude calculator 318. In the voltage magnitude calculator 318, the magnitude of the high-frequency components of the inductor voltage is calculated with the following equation:

$$\vert {V}_{L {1}_{S F}} \vert = \sqrt{{( {V}_{L {1}_{s f}}^{d} )}^{2} + {( {V}_{L {1}_{s f}}^{q} )}^{2}}$$

The voltage magnitude calculator 318 outputs the magnitude of the high-frequency components of the inductor voltage (|V_{L1}_{_{SF}}|).

A virtual admittance metric is defined at 212 as a ratio of the magnitude of the high-frequency components of the inductor current to the magnitude of the high-frequency components of the inductor voltage. That is, the virtual admittance metric is generated at the admittance calculator 320 as the following:

$$\vert {Y}_{L {1}_{S F}} \vert = \frac{\vert {i}_{L {1}_{S F}} \vert}{\vert {V}_{L {1}_{S F}} \vert}$$

To detect a fault, the virtual admittance or fault index 322 is compared at 214 to a fault threshold 324. A fault is signaled at 216 if the virtual admittance metric is less than the fault threshold 322. In the example embodiment, the virtual admittance metric and the fault threshold are compared using a comparator 330.

The output of the comparator 330 is a fault signal 336 that may be communicated to control an indicator 338. The fault signal 336 indicates a fault at the indicator 338. The indicator 338 may be a screen display or a warning light as a visual indicator or an audible indicator such as a speaker, buzzer or the like. The screen display may be located at or near the switch at or near the controller 138 or may be located remotely. Combinations of indicators may also be used.

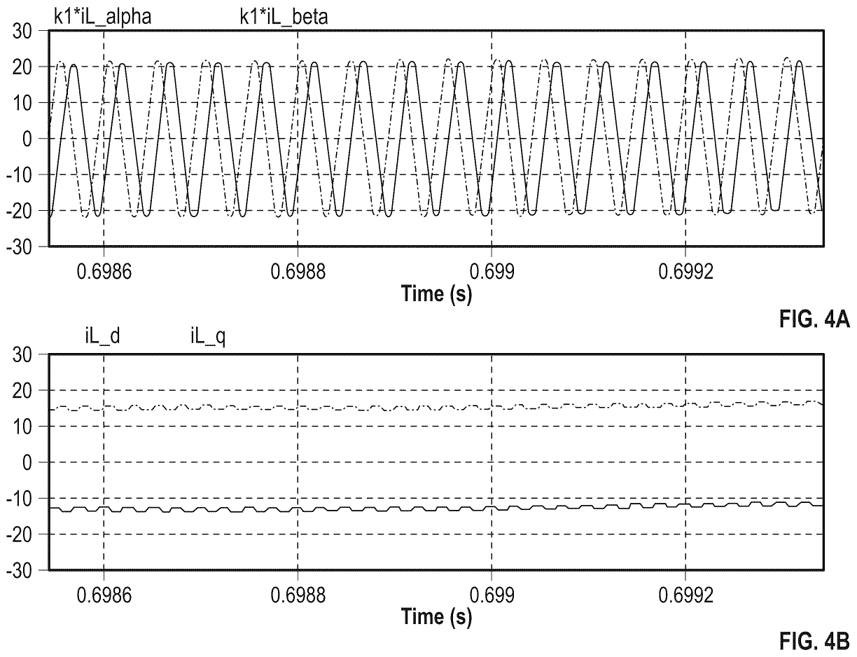

FIG. 4A is an example of a steady-state response of the α-β components of the inductor current. The steady-state response of the inductor current after being transformed into d-q components by the α-β/d-q transformer 306 is shown in FIG. 4B. Ideally, as shown in the simulation waveforms, sinusoidal α-β currents are observed.

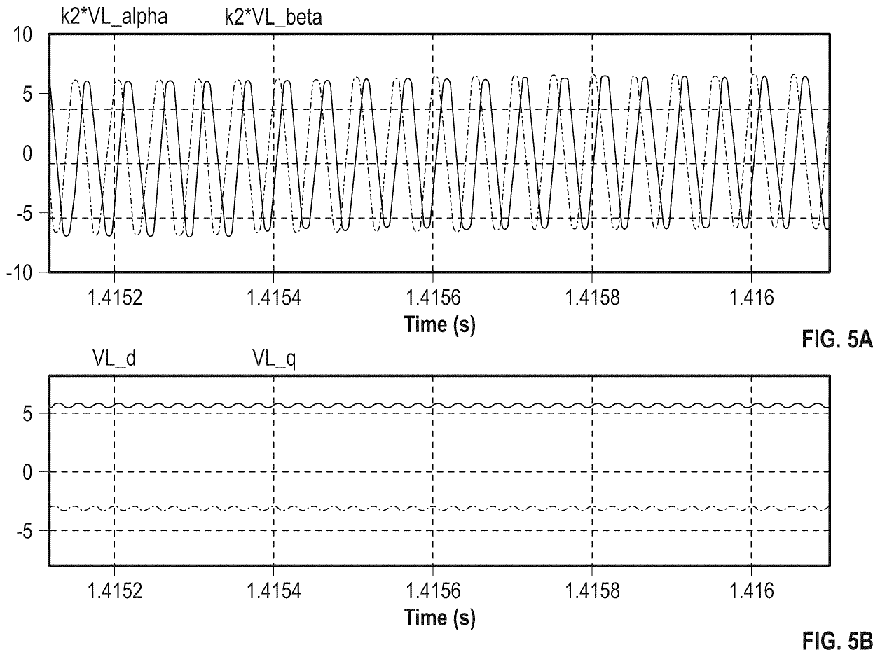

FIG. 5A is an example of a steady-state response of the α-β components of the inductor voltage. The steady-state response of the inductor voltage after being transformed into d-q components by the α-β/d-q transformer 306 is shown in FIG. 5B. As shown in the upper waveforms, (V_(L1_sf)\hat{ }α) and (V_(L1_sf)\hat{ }β) have 90° phase shift with a sinusoidal shape. In addition, the bottom waveform presents the d-q axes inductor voltage waveforms (V_(L1_sf)\hat{ }d) and

$$( {V}_{L {1}_{s f}}^{q} ) .$$

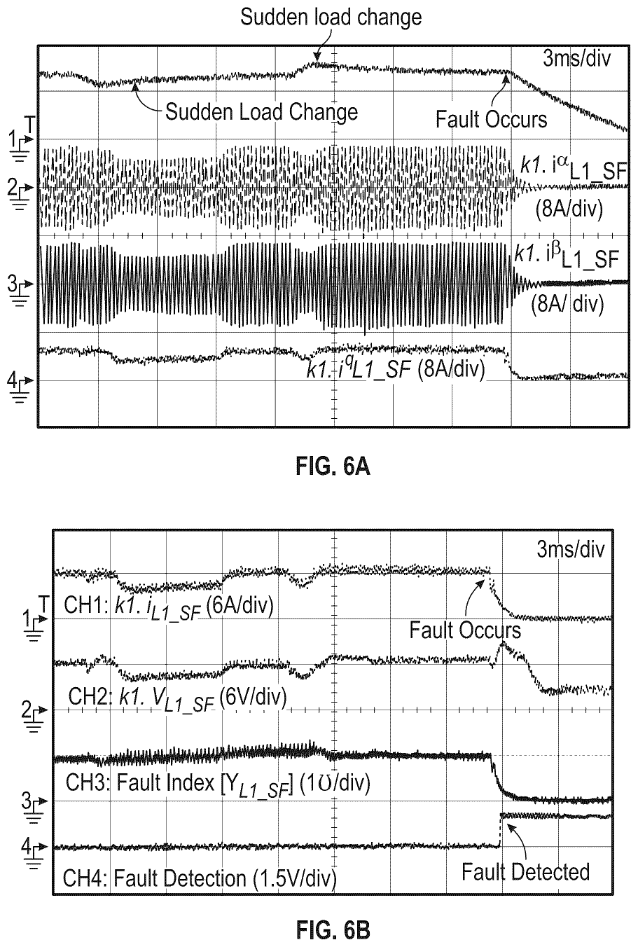

FIG. 6A is an example of a steady state response of the virtual admittance under different load changes. FIG. 6B is an example of a steady state response of the virtual admittance and a fault detection signal. Under load changes, the steady state response of the virtual admittance metric is shown in FIG. 6B as CH3. The virtual admittance can suppress the perturbation even though other parameters go through larger perturbations since the load change influences both the magnitude of the high-frequency components of the inductor current and the magnitude of the high-frequency components of the inductor voltage. False alarms are minimized in the case of load condition changes because the virtual admittance can suppress the perturbations. It is observed that the amplitude of the α-β components of the inductor current and the inductor voltage at the switching frequency decreases after an open switch fault occurrence. The virtual admittance is less sensitive to load changes due to a cancellation effect by the division in calculating the virtual admittance, This is because the load changes are reflected in the magnitude of the high-frequency components of the inductor voltage and the magnitude of the high-frequency components of the inductor current. After an open switch fault, the virtual admittance decreases to zero and a fault detection signal is triggered since the virtual admittance is lower than the fault threshold. In FIG. 6B, the fault detection signal is depicted as CH4.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for detecting a fault of a switch in a power converter, the switch is controlled by a pulse width modulated (PWM) control signal and powered by a power source, the method comprising:
measuring an inductor current passing through an inductor of the power converter;
determining an inductor voltage across the inductor;
extracting a high-frequency component of the inductor current at a switching frequency;
extracting a high-frequency component of the inductor voltage at a switching frequency;
calculating a magnitude of the high-frequency component of the inductor current;
calculating a magnitude of the high-frequency component of the inductor voltage;
defining a ratio of the magnitude of the high-frequency component of the inductor current to the magnitude of the high-frequency component of the inductor voltage;
comparing the ratio to a fault threshold; and
signaling a fault in the switch in response to the ratio being less than the fault threshold.

2. The method of claim 1 wherein measuring the inductor current comprises measuring the inductor current at a current sensor positioned between the power source and the switch.

3. The method of claim 1 further comprising determining the inductor voltage comprises determining the inductor voltage from a duty ratio of the PWM control signal, an input voltage of the power source and an DC link voltage for the power converter.

4. The method of claim 3 wherein when the switch is in an on state, determining the inductor voltage as equal to the input voltage of the power source minus the DC link voltage; and wherein when the switch is in an off state, determining the inductor voltage as equal to a negative magnitude of the DC link voltage.

5. The method of claim 1 further comprising transforming the high-frequency component of the inductor current and the high-frequency component of the inductor voltage to a direct component and a quadrature component of the inductor voltage in accordance with a direct-quadrature-zero transformation.

6. The method of claim 5 wherein calculating the magnitude of the high-frequency component of the inductor current comprises calculating the magnitude of the high-frequency component of the inductor current from the direct component and the quadrature component of the inductor current.

7. The method of claim 5 wherein calculating the magnitude of the high-frequency component of the inductor voltage comprises calculating the magnitude of the high-frequency component of the inductor voltage from the direct component and the quadrature component of the inductor voltage.

8. The method of claim 5 wherein transforming comprises transforming an α-axis component and a β-axis component of the inductor current to the direct component and the quadrature component of the inductor current.

9. The method of claim 8 wherein transforming comprises transforming an α-axis component and a β-axis component of the inductor voltage to the direct component and the quadrature component of the inductor voltage.

10. The method of claim 1 wherein the ratio corresponds to a virtual admittance metric.

11. A method for detecting a fault of a switch in a power converter, the switch is controlled by a pulse width modulated (PWM) control signal and powered by a power source, the method comprising:
measuring an inductor current passing through an inductor, the inductor is electrically coupled between the power source and the switch;
determining an inductor voltage across the inductor;
extracting a high-frequency component of the inductor current at a switching frequency, thereby forming an α-axis component of the inductor current;
extracting a high-frequency component of the inductor voltage at a switching frequency, thereby forming an α-axis component of the inductor voltage;
generating a β-axis component of the inductor current from the extracted high-frequency component of the inductor current, wherein the β-axis component of the inductor current is at 90 degree phase shift from the α-axis component of the inductor current;
generating a β-axis component of the inductor voltage from the extracted high-frequency component of the inductor voltage, wherein the β-axis component of the inductor voltage is at 90 degree phase shift from the α-axis component of the inductor voltage;
transforming the α-axis component and the β-axis component of the inductor current to a direct component and a quadrature component of the inductor current in accordance with a direct-quadrature-zero transformation;
transforming the α-axis component and the β-axis component of the inductor voltage to a direct component and a quadrature component of the inductor voltage in accordance with a direct-quadrature-zero transformation;
calculating a magnitude of the high-frequency component of the inductor current from the direct component and the quadrature component of the inductor current;
calculating a magnitude of the high-frequency component of the inductor voltage from the direct component and the quadrature component of the inductor voltage;
defining a virtual admittance metric as a ratio of the magnitude of the high-frequency component of the inductor current to the magnitude of the high-frequency component of the inductor voltage;
comparing the virtual admittance metric to a fault threshold; and
signaling a fault in the switch in response to the virtual admittance being less than the fault threshold.

12. The method of claim 11 further comprising determining the inductor voltage comprises determining the inductor voltage from a duty ratio of the PWM control signal, an input voltage of the power source and an DC link voltage for the power converter.

13. The method of claim 12 wherein when the switch is in an on state, the inductor voltage is equal to the input voltage of the power source minus the DC link voltage.

14. The method of claim 13 wherein when the switch is in an off state, the inductor voltage is equal to a negative magnitude of the DC link voltage.

15. The method of claim 11 further comprising determining the DC link voltage comprises determining the DC link voltage based on a voltage across a DC bus capacitor.

16. The method of claim 11 wherein the high-frequency components of the inductor current and the high-frequency components of the inductor voltage are extracted using a band-pass filter.

17. The method of claim 1 wherein the β-axis component of the inductor current and the β-axis component of the inductor voltage are generated using an all-pass filter.

18. The method of claim 1 wherein signaling the fault comprises communicating the fault signal to a display, generating a visual indicator or generating an audible indicator.

19. A system comprising:
a pulse width modulator generating a pulse width modulated (PWM) control signal;
a power converter having an inductor and a switch receiving the pulse width modulated control signal and powered by a power source;
a current sensor generating a current signal corresponding to an inductor current passing through the inductor;
a controller programmed to
determine an inductor voltage across the inductor;
extract a high-frequency component of the inductor current at a switching frequency, thereby forming an α-axis component of the inductor current;
extract a high-frequency component of the inductor voltage at a switching frequency, thereby forming an α-axis component of the inductor voltage;
generate a β-axis component of the inductor current from the extracted high-frequency component of the inductor current, wherein the β-axis component of the inductor current is at 90 degree phase shift from the α-axis component of the inductor current;
generate a β-axis component of the inductor voltage from the extracted high-frequency component of the inductor voltage, wherein the β-axis component of the inductor voltage is at 90 degree phase shift from the α-axis component of the inductor voltage;
transform the α-axis component and the β-axis component of the inductor current to a direct component and a quadrature component of the inductor current in accordance with a direct-quadrature-zero transformation;
transform the α-axis component and the β-axis component of the inductor voltage to a direct component and a quadrature component of the inductor voltage in accordance with a direct-quadrature-zero transformation;
calculate a magnitude of the high-frequency component of the inductor current from the direct component and the quadrature component of the inductor current;
calculating a magnitude of the high-frequency component of the inductor voltage from the direct component and the quadrature component of the inductor voltage;
define a virtual admittance metric as a ratio of the magnitude of the high-frequency component of the inductor current to the magnitude of the high-frequency component of the inductor voltage;
compare the virtual admittance metric to a fault threshold; and
an indicator indicating the fault of a switch in a power converter in response to the virtual admittance being less than the fault threshold.

20. The system of claim 19 wherein the controller is programmed to determine the inductor voltage based on a duty ratio of the PWM control signal, an input voltage of the power source and an DC link voltage for the power converter.
